(19) United States
(12) Patent Application Publication
(10) Pub. No.: US 2025/0351726 A1
(43) Pub. Date: Nov. 13, 2025

(54) SUBSTRATE TEMPERATURE CONTROL WITH INTEGRATED THERMOELECTRIC COOLING SYSTEM

(71) Applicant: LAM RESEARCH CORPORATION, Fremont, CA (US)

(72) Inventor: Siyuan TIAN, Newark, CA (US)

(21) Appl. No.: 18/871,389

(22) PCT Filed: Jun. 1, 2023
(86) PCT No.: PCT/US2023/024144

§ 371 Date: Dec. 3, 2024

Related U.S. Application Data
(60) Provisional application No. 63/349,694, filed on Jun. 7, 2022.

(51) Int. Cl. H10N 10/17; F25B 21/04; H01L 21/687

(52) U.S. Cl. CPC H10N 10/17; F25B 21/04; H01L 21/68785

(57) ABSTRACT

A temperature control system for a substrate support in a processing chamber includes a manifold assembly configured to supply a liquid coolant at a first temperature from a first channel of a coolant assembly to the processing chamber, supply the liquid coolant at a second temperature from a second channel of the coolant assembly to the processing chamber, and supply return coolant from the processing chamber to the coolant assembly. A thermoelectric module arranged in a flow path between the manifold assembly and the coolant assembly is configured to receive the return coolant from the manifold assembly, either one of heat and cool the return coolant, and supply heated return coolant and cooled return coolant to the coolant assembly.

### CROSS-REFERENCE TO RELATED APPLICATIONS

This application claims the benefit of U.S. Provisional Application No. 63/349,694, filed on Jun. 7, 2022. The entire disclosure of the application referenced above is incorporated herein by reference.

### FIELD

The present disclosure relates to temperature control of substrate supports in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, dielectric etch, and/or other etch, deposition, or cleaning processes. A substrate may be arranged on a substrate support, such as a pedestal, an electrostatic chuck (ESC), etc. in a processing chamber of the substrate processing system. During etching, etch gas mixtures including one or more gases may be introduced into the processing chamber and plasma may be used to initiate chemical reactions.

### SUMMARY

A temperature control system for a substrate support in a processing chamber includes a manifold assembly configured to supply a liquid coolant at a first temperature from a first channel of a coolant assembly to the processing chamber, supply the liquid coolant at a second temperature from a second channel of the coolant assembly to the processing chamber, and supply return coolant from the processing chamber to the coolant assembly. A thermoelectric module arranged in a flow path between the manifold assembly and the coolant assembly is configured to receive the return coolant from the manifold assembly, either one of heat and cool the return coolant, and supply heated return coolant and cooled return coolant to the coolant assembly. The thermoelectric module may be a single stage or multi-stage thermoelectric cooler.

In other features, the thermoelectric module includes a first conductive plate coupled to a first side of the thermoelectric module, the first conductive plate including first coolant channels in fluid communication with the manifold assembly and the coolant assembly to supply the return coolant from the manifold assembly to the coolant assembly, and a second conductive plate coupled to a second side of the thermoelectric module, the second conductive plate including second coolant channels in fluid communication with the manifold assembly and the coolant assembly to supply the return coolant from the manifold assembly to the coolant assembly. The coolant assembly includes a cold coolant reservoir and a hot coolant reservoir. The manifold assembly supplies the liquid coolant at the first temperature from the cold coolant reservoir and supplies the liquid coolant at the second temperature from the hot coolant reservoir.

In other features, the first coolant channels supply the return coolant from the manifold assembly to the cold coolant reservoir and the second coolant channels supply the return coolant from the manifold assembly to the hot coolant reservoir. The manifold assembly includes a first valve assembly configured to supply the liquid coolant from the cold coolant reservoir to the processing chamber, a second valve assembly configured to supply the liquid coolant from the hot coolant reservoir to the processing chamber, and a third valve assembly configured to supply the return coolant from the processing chamber to the thermoelectric module. The third valve assembly is configured to selectively supply the return coolant to either one of the first conductive plate and the second conductive plate. At least one of the first valve assembly, the second valve assembly and the third valve assembly comprises a 3-way valve.

In other features, the temperature control system further includes a

temperature controller configured to control the manifold assembly to selectively control supply of the return coolant to the thermoelectric module and control a voltage supplied to the thermoelectric module to cool and heat the return coolant supplied to the coolant assembly. The thermoelectric module is located below the manifold assembly. The thermoelectric module is located laterally adjacent to the manifold assembly.

In other features, a substrate processing system includes the temperature control system and further includes the coolant assembly. The coolant assembly is located below a floor of a fabrication room and the thermoelectric module is arranged above the floor. The coolant assembly and the thermoelectric module are located below a floor of a fabrication room.

A temperature control system for a processing chamber includes a thermoelectric module arranged in a flow path between the processing chamber and a coolant assembly, the thermoelectric module configured to receive return coolant from the processing chamber, either one of heat and cool the return coolant, and supply heated return coolant and cooled return coolant to the coolant assembly. A temperature controller is configured to selectively control supply of the return coolant to the thermoelectric module and control a voltage supplied to the thermoelectric module to cool and heat the return coolant supplied to the coolant assembly.

In other features, the thermoelectric module includes a first conductive plate coupled to a first side of the thermoelectric module, the first conductive plate including first coolant channels to supply the return coolant to the coolant assembly, and a second conductive plate coupled to a second side of the thermoelectric module, the second conductive plate including second coolant channels to supply the return coolant to the coolant assembly. The thermoelectric module supplies the return coolant from the first conductive plate to a cold coolant reservoir of the coolant assembly and supplies the return coolant from the second conductive plate to a hot coolant reservoir of the coolant assembly.

In other features, the temperature control system further includes a return valve assembly configured to supply the return coolant from the processing chamber to either one of the first conductive plate and the second conductive plate of the thermoelectric module. The return valve assembly includes a 3-way valve. The temperature controller is configured to control the return valve assembly to selectively supply the return coolant to the first conductive plate or the second conductive plate of the thermoelectric module. The temperature controller is configured to control supply of voltage to the thermoelectric module to selectively cool and heat the return coolant within the first conductive plate and the second conductive plate, respectively.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing system according to the present disclosure;

FIG. 2A is an example temperature control system including a thermoelectric assembly according to the present disclosure;

FIG. 2B is another example temperature control system including a thermoelectric assembly according to the present disclosure;

FIG. 2C is another example temperature control system including a thermoelectric assembly according to the present disclosure;

FIG. 3 is an example thermoelectric assembly according to the present disclosure; and

FIG. 4 illustrates steps of an example method for controlling a temperature of a substrate support according to the present disclosure.

In the drawings, reference numbers may be reused to identify similar and/or identical elements.

### DETAILED DESCRIPTION

Cooling systems may be configured to cool substrate supports such as electrostatic chucks (ESCs) with a coolant fluid. For example, coolant fluids such as high-pressure cooled gases or various liquid coolants flow through coolant channels in a baseplate of a substrate support. Cooling capacity and temperature range may be limited due to mechanical limitations.

For example, a dual temperature control system may comprise a plurality of valves (e.g., 3-way supply valves) to mix hot and cold coolant supplied from a coolant assembly to the substrate support and a return valve to control flow of coolant back to the coolant assembly. The coolant assembly supplies both hot and cold coolant from respective reservoirs (e.g., a hot coolant reservoir and a cold coolant reservoir). The coolant flowing back from the substrate support (return coolant) via the return valve is mixed with hot or cold coolant and then supplied to the respective reservoirs. In other words, since the same return coolant is supplied to both reservoirs, the return coolant is heated prior to being supplied to the hot coolant reservoir and cooled prior to being supplied to the cold coolant reservoir.

Typically, there is a large temperature differential between the temperature of the return coolant (prior to being heated or cooled) and the temperature of the coolant in the respective reservoirs. Accordingly, the coolant assembly needs significant heating and cooling capacity to provide a desired range of temperature control of the substrate support (e.g., from −60 to 80° C.) and adequate balancing of the return coolant temperature. However, constraints such as power requirements, cost, footprint, and cooling technology limit the temperature control range of the coolant assembly.

A dual temperature control system according to the present disclosure comprises a thermoelectric module configured to heat and cool the return coolant and supply the heated/cooled return coolant to the respective reservoirs within the coolant assembly. For example, the thermoelectric module is a single stage or multi-stage thermoelectric cooler (TEC). Since the thermoelectric module regulates the temperature of the return coolant, the return coolant does not need to be mixed with hot or cold coolant prior to being supplied to the coolant assembly. Accordingly, the load on the coolant assembly is reduced.

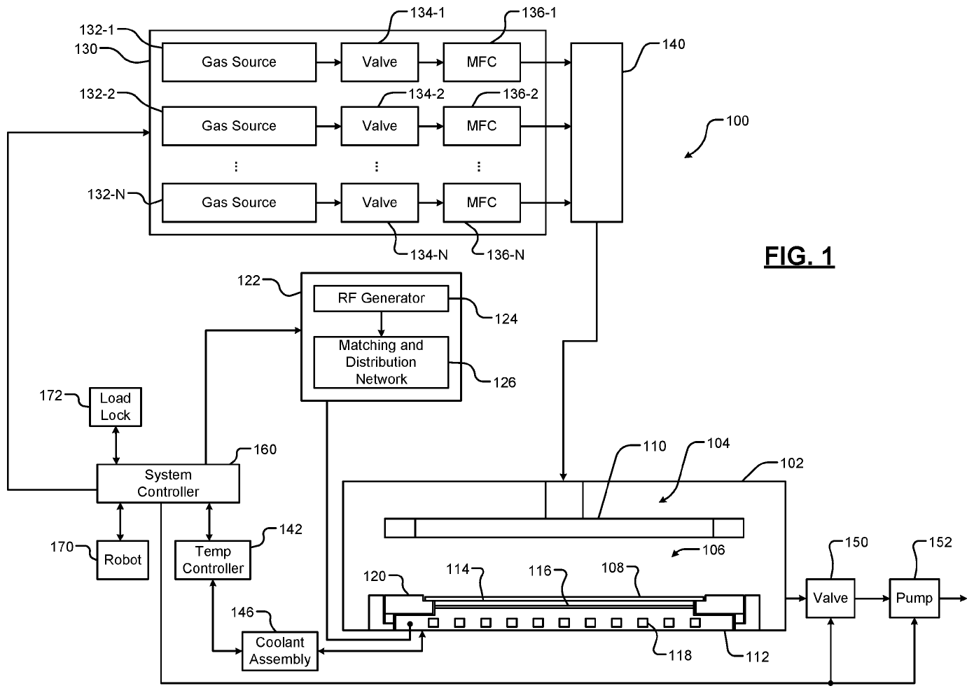

Referring now to FIG. 1, an example substrate processing system 100 is shown. For example only, the substrate processing system 100 may be used for performing substrate processing that requires temperature control (e.g., cryogenic etching using RF plasma). The substrate processing system 100 includes a processing chamber 102 that encloses other components of the substrate processing system 100 and contains the RF plasma. The substrate processing chamber 102 includes an upper electrode 104 and a substrate support 106, such as an ESC. During operation, a substrate 108 is arranged on the substrate support 106. While a specific substrate processing system 100 and processing chamber 102 are shown as an example, the principles of the present disclosure may be applied to other types of substrate processing systems and processing chambers, such as a substrate processing system that generates plasma in-situ or implements remote plasma generation and delivery (e.g., using a plasma tube, a microwave tube).

For example only, the upper electrode 104 may include a gas distribution device such as a showerhead 110 that introduces and distributes process gases. The showerhead 110 may include a stem portion including one end connected to a top surface of the processing chamber 102. A base portion is generally cylindrical and extends radially outwardly from an opposite end of the stem portion at a location that is spaced from the top surface of the processing chamber. A substrate-facing surface or faceplate of the base portion of the showerhead 110 includes a plurality of holes through which process gas or purge gas flows. Alternately, the upper electrode 104 may include a conducting plate and the process gases may be introduced in another manner.

The substrate support 106 includes a conductive baseplate 112 that acts as a lower electrode. The baseplate 112 supports a ceramic layer 114. A bond layer (e.g., an adhesive and/or thermal bond layer) 116 may be arranged between the ceramic layer 114 and the baseplate 112. The baseplate 112 may include one or more coolant channels 118 for flowing coolant through the baseplate 112. The substrate support 106 may include an edge ring 120 arranged to surround an outer perimeter of the substrate 108.

An RF generating system 122 generates and outputs an RF voltage to one of the upper electrode 104 and the lower electrode (e.g., the baseplate 112 of the substrate support 106). The other one of the upper electrode 104 and the baseplate 112 may be DC grounded, AC grounded or floating. In the present example, the RF voltage is supplied to the lower electrode. For example only, the RF generating system 122 may include an RF voltage generator 124 that generates the RF voltage that is fed by a matching and distribution network 126 to the upper electrode 104 or the baseplate 112. In other examples, the plasma may be generated inductively or remotely. Although, as shown for example purposes, the RF generating system 122 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more etch gases and mixtures thereof. The gas sources may also supply carrier and/or purge gas. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 110.

A temperature controller 142 may communicate with a coolant assembly 146 to control coolant flow through the channels 118. The coolant assembly 146 according to the present disclosure is configured as a dual channel chiller (e.g., including a coolant pump and respective reservoirs) that supplies coolant to the coolant channels 118 via a manifold and valves as described below in more detail. The temperature controller 142 operates the coolant assembly 146 to selectively flow the coolant through the channels 118 to cool the substrate support 106. A thermoelectric module (not shown in FIG. 1) is configured to heat and cool return coolant flowing from the substrate support 106 to the coolant assembly 146.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

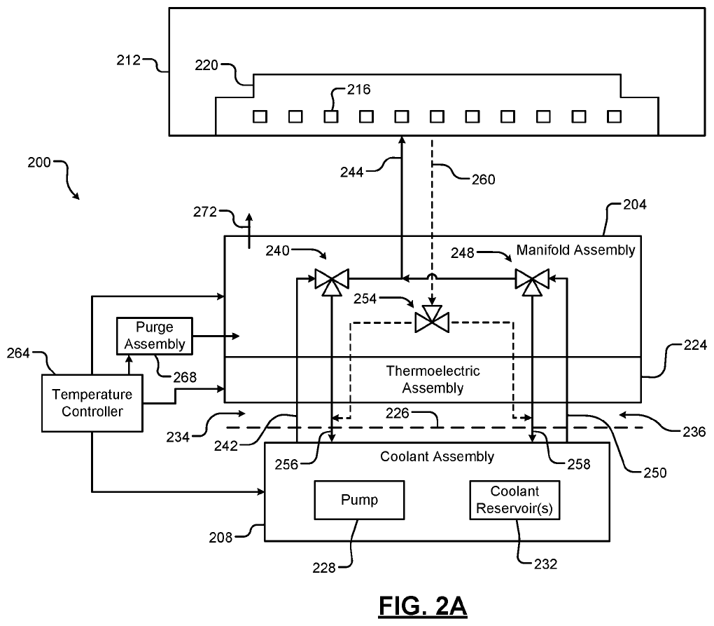

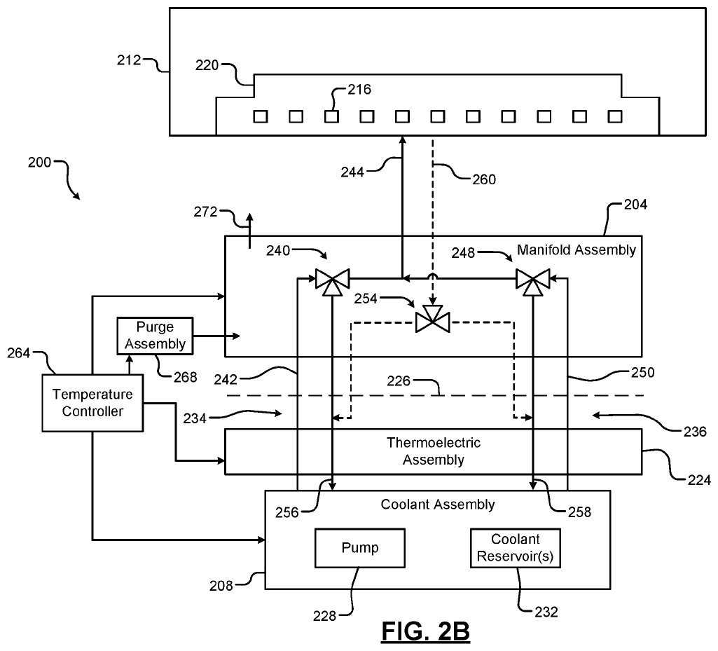

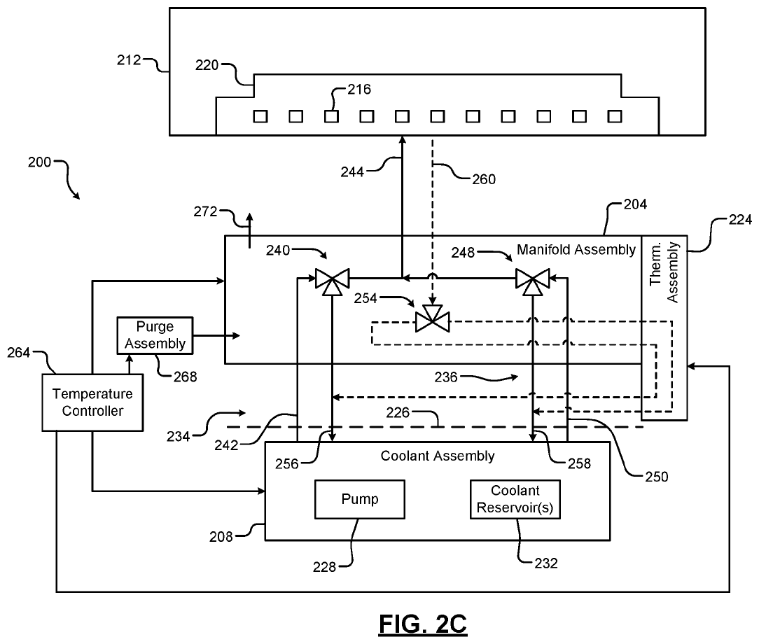

Referring now to FIGS. 2A-2C, a temperature control system (e.g., a dual temperature control system) 200 includes a manifold assembly 204 arranged between a coolant assembly 208 and a processing chamber 212 (e.g., a processing station or module). The temperature control system 200 and the manifold assembly 204 supply a liquid coolant to coolant channels 216 of a substrate support (e.g., a baseplate of a pedestal, ESC, etc.) 220. For example, the processing chamber 212 is configured to perform a process on a substrate arranged on the substrate support 220. The temperature control system 200 according to the present disclose includes a thermoelectric assembly 224 as described below in more detail.

As shown, the thermoelectric assembly 224 is arranged between the manifold assembly 204 and the coolant assembly 208 above a fabrication room floor 226. In other examples, the thermoelectric assembly 224 may be arranged within the manifold assembly 204 or in an enclosure with the manifold assembly 204, below the floor 226, within the coolant assembly 208, etc. For example, as shown in FIG. 2B, the thermoelectric assembly 224 is arranged below the floor 226. As shown in FIG. 2C, the thermoelectric assembly 224 is arranged adjacent to (i.e., laterally adjacent to) the manifold assembly 204.

The coolant assembly 208, the manifold assembly 204, and the thermoelectric assembly 224 are configured to provide accurate cooling of the substrate support 220 (e.g., in a range from −60 or below to 80° C.) while minimizing a temperature differential between return coolant and coolant within the coolant assembly 208. For example, the coolant assembly 208 is configured as a dual channel chiller including a pump 228 and one or more coolant reservoirs 232 storing liquids at different temperatures. A first one of the coolant reservoirs 232 (e.g., a cold coolant reservoir) may store liquid coolant that is maintained in a first temperature range (e.g., from −60° C. or below to 20° C.) while a second one of the coolant reservoirs 232 (e.g., a hot coolant reservoir) stores liquid coolant that is maintained in a second temperature range (e.g., from 20° C. to 80° C.). Accordingly, the coolant assembly 208 provides coolant via both a cold side (e.g., a cold or cold-side channel 234 including cold supply and return tubing) and a hot side (e.g., a hot or hot-side channel 236 including hot supply and return tubing) to the manifold assembly 204.

The manifold assembly 204 includes a cold supply valve or valve assembly 240 (e.g., a 3-way valve, as shown, or a combination of valves) in fluid communication with a cold channel supply tube 242 and an inlet 244 of the coolant channels 216. Conversely, the manifold assembly 204 includes a hot supply valve or valve assembly 248 (e.g., a 3-way valve, as shown, or a combination of valves) in fluid communication with a hot channel supply tube 250 and the inlet 244 of the coolant channels 216. A return valve or valve assembly 254 (e.g., a 3-way valve, as shown, or a combination of valves) is arranged between and in fluid communication with a cold channel return tube 256, a hot channel return tube 258, and an outlet 260 of the coolant channels 216. The cold supply valve 240 and the hot supply valve 248 are also in fluid communication with the cold channel return tube 256 and the hot channel return tube 258, respectively. Although shown as 3-way valves, any of the valves 240, 248, and 254 may be replaced with other valve arrangements. For example, each 3-way valve may be replaced with multiple valves arranged to respectively supply liquid coolant to and from the substrate support 220.

In this manner, the coolant assembly 208 provides cold liquid coolant through the cold supply valve 240 and cold liquid coolant (i.e., cold return coolant) returns to the coolant assembly 208 through the return valve 254 and the thermoelectric assembly 224. The thermoelectric assembly 224 is configured to cool the cold return coolant and supply the cold return coolant to the coolant assembly 208. Further, the cold supply valve 240 is configured to selectively allow liquid coolant to flow from the coolant assembly 208, into the cold supply valve 240, and back into the coolant assembly 208 to maintain temperature and pressure consistency when cold liquid coolant is not being supplied to the coolant channels 216.

Similarly, the coolant assembly 208 provides hot liquid coolant through the hot supply valve 248 and hot liquid coolant (i.e., hot return coolant) returns to the coolant assembly 208 through the return valve 254 and the thermoelectric assembly 224. The thermoelectric assembly 224 is configured to heat the hot return coolant and supply the hot return coolant to the coolant assembly 208. Further, the hot supply valve 248 is configured to selectively allow liquid coolant to flow from the coolant assembly 208, into the hot supply valve 248, and back into the coolant assembly 208 when hot liquid coolant is not being supplied to the coolant channels 216.

A temperature controller 264 controls the coolant assembly 208 and the manifold assembly 204 to supply liquid coolant to the substrate support 220 to maintain the substrate support 220 at a desired temperature. For example, the temperature controller 264 selectively supplies the liquid coolant via the cold channel 234 and/or the hot channel 236, blends the liquid coolant from the cold channel 234 and the hot channel 236, etc. by controlling the valves 240 and 248 to maintain the desired temperature. The temperature controller 264 further controls the return valve 254 to supply return coolant to the coolant assembly 208. The temperature controller 264 controls the thermoelectric assembly 224 to selectively heat or cool return coolant supplied to the coolant assembly 208 as described below in more detail.

In some examples, the manifold assembly 204 may be actively purged (e.g., with compressed dry air, a purge gas such as molecular nitrogen) during processing to prevent and/or remove condensation within the manifold assembly 204. For example, a purge assembly (e.g., a purge gas source, purge valve, etc.) 268 in fluid communication with an interior of the manifold assembly 204 is configured to selectively flow purge gas to purge condensation. The purge assembly 268 may be responsive to the temperature controller 264, the system controller 160, etc. The purge gas and condensation are vented out of the manifold assembly via a purge vent or outlet 272 in communication with atmosphere.

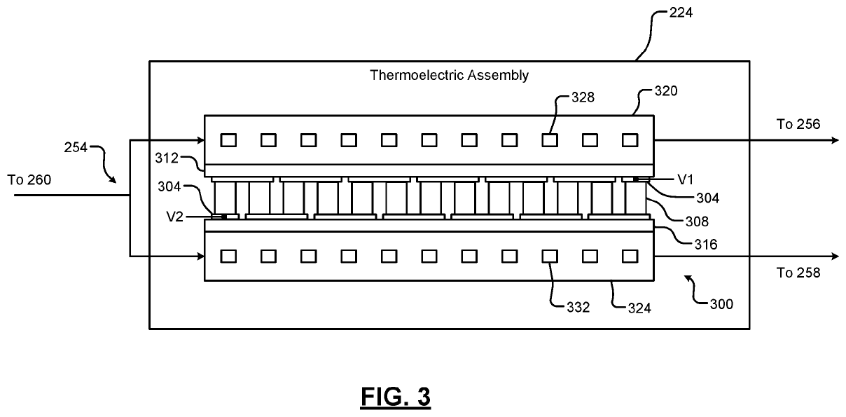

FIG. 3 shows an example of the thermoelectric assembly 224 in more detail. The thermoelectric assembly 224 includes a thermoelectric module 300 (e.g., a thermoelectric cooler, or TEC). For example, the thermoelectric module 300 is a solid-state planar TEC configured function according to the Peltier effect. Although shown as a single stage TEC, the thermoelectric module 300 may be implemented as a multi-stage TEC. First and second voltages V1 and V2 (e.g., a positive DC voltage and a negative DC voltage) are applied to respective conductive electrodes or pads 304 (e.g., copper pads). Current flows from one side of the thermoelectric module 300 to the other through a series of thermoelectric semiconductor elements 308 disposed between substrates 312 and 316 (e.g., ceramic substrates). The semiconductor elements 308 may be comprised of thermoelectric materials including, but not limited to, bismuth telluride (Bi₂Te₃), lead telluride (PbTe), silicon germanium (SiGe), and bismuth-antimony (Bi—Sb).

Adjacent pairs of the semiconductor elements 308 comprise an N-type and a P-type semiconductor element. As current flows through the semiconductor elements (i.e., alternating between the N-type and P-type semiconductor elements), one of the substrates 312 and 316 is heated while the other is cooled. More specifically, heat flows from a cold side substrate (e.g., the substrate 312) to a hot side substrate (e.g., the substrate 316) or vice versa based on a direction of the current flow through the semiconductor elements 308. Reversing a polarity of the current reverses a direction of the flow of heat.

The thermoelectric module 300 is coupled to respective conductive (e.g., aluminum) plates 320 and 324 (e.g., a cold side plate 320 and a hot side plate 324). For example, the conductive plates 320 and 324 are coupled to the substrates 312, and 316, respectively, using a thermally conductive, low modulus adhesive, such as a silicone adhesive. The plates 320 and 324 include respective coolant channels 328 and 332. For example, the coolant channels 328 and 332 are in fluid communication with the return valve 254 to receive return coolant from the outlet 260. The coolant channels 328 of the cold side plate 320 are in fluid communication with and supply return coolant to the cold channel return tube 256. Conversely, the coolant channels 332 of the hot side plate 324 are in fluid communication with and supply return coolant to the hot channel return tube 258.

In this manner, the thermoelectric module 300 cools the return coolant flowing from the outlet 260 and through the return valve 254 prior to supplying the coolant to the coolant assembly 208 (i.e., to a cold coolant reservoir). For example, the return coolant flowing through the coolant channels 328 releases heat into the cold side plate 320, thereby cooling the return coolant flowing through the coolant channels 328 and supplied to the cold channel return tube 256. Conversely, the thermoelectric module 300 heats the return coolant flowing from the outlet 260 and through the return valve 254 prior to supplying the coolant to the coolant assembly 208 (i.e., to a hot coolant reservoir). The return coolant flowing through the coolant channels 332 absorbs heat from the hot side plate 324, thereby heating the return coolant flowing through the coolant channels 332 and supplied to the hot channel return tube 258.

Accordingly, heating and cooling power used by the coolant assembly 208 is reduced and heating/cooling efficiency is increased. Further, cooling capacity at low operating temperatures is increased, coefficient of performance is increased, and the footprint of the cooling assembly 208 can be decreased.

The temperature controller 264 controls the thermoelectric module 300 to selectively heat or cool return coolant supplied to the coolant assembly 208. For example, the temperature controller 264 implements PID or other closed loop control to determine an amount of heat transfer required to obtain a desired (e.g., setpoint) temperature adjustment of the substrate support 220. The temperature controller 264 selectively adjusts (e.g., using DC or pulse width modulation) the voltages supplied to the thermoelectric module 300 to increase or decrease the amount of heat transferred to and from the return coolant.

For example, while supplying hot liquid coolant to heat the substrate support 220, the temperature controller 264 controls the return valve 254 to supply the return coolant to the coolant assembly 208 through the hot side plate 324 of the thermoelectric module 300 and controls the voltages V1 and V2 accordingly. Conversely, while supplying cold liquid coolant to cool the substrate support 220, the temperature controller 264 controls the return valve 254 to supply the return coolant to the coolant assembly 208 through the cold side plate 320 of the thermoelectric module 300 while controlling the voltages V1 and V2.

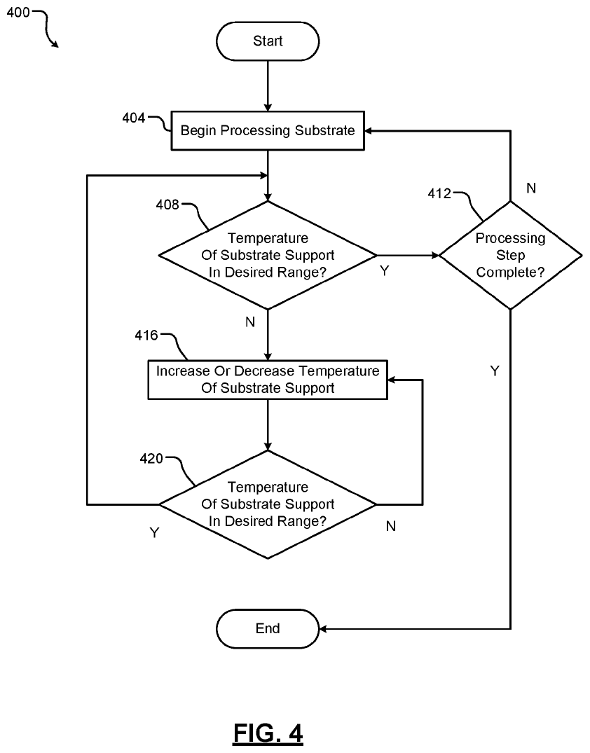

FIG. 4 illustrates steps of an example method 400 for controlling a temperature of a substrate support according to the present disclosure. At 404, a processing begins. For example, etching, deposition, or another processing step is performed on a substrate arranged on a substrate support. At 408, the method 400 (e.g., the temperature controller 264) determines whether a temperature of the substrate support is within a desired range. For example, the temperature controller 264 may receive signals from temperature sensors or other signals indicative of a temperature of the substrate support and determine whether the temperature is within the desired range (e.g., above a lower threshold and below an upper threshold). If true, the method 400 continues to 412. If false, the method 400 continues to 416. At 412, the method 400 determines whether the processing step is complete. If true, the method 400 ends. If false, the method 400 continues processing while monitoring the temperature at 408.

At 416, the method 400 (e.g., the temperature controller 264) increases or decreases the temperature of the substrate support into the desired range. For example, the temperature controller 264 controls components of the temperature control system 200 to increase or decrease the temperature of the substrate support while continuing to monitor the temperature and compare the temperature to the desired range.

For example, if the temperature is above the desired range, the temperature controller 264 controls the supply valve 240 to supply cold liquid coolant to the substrate support 220 while controlling the return valve 254 to supply the return coolant to the coolant assembly through the cold side plate 320 of the thermoelectric module 300. Conversely, if the temperature is below the desired range, the temperature controller 264 controls the supply valve 248 to supply hot liquid coolant to the substrate support 220 while controlling the return valve 254 to supply the return coolant to the coolant assembly through the hot side plate 324 of the thermoelectric module 300.

At 420, the method 400 (e.g., the temperature controller 264) determines whether the temperature is within the desired range. If true, the method 400 continues to 404. If false, the method 400 proceeds to 416 and continues to adjust the temperature control system 200 (e.g., by increasing or decreasing the rate of flow of cold liquid coolant or hot liquid coolant, as needed) until the temperature is within the desired range.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A temperature control system for a substrate support in a processing chamber, temperature control system comprising:
a manifold assembly configured to (i) supply a liquid coolant at a first temperature from a first channel of a coolant assembly to the processing chamber, (ii) supply the liquid coolant at a second temperature from a second channel of the coolant assembly to the processing chamber, and (iii) supply return coolant from the processing chamber to the coolant assembly; and
a thermoelectric module arranged in a flow path between the manifold assembly and the coolant assembly, the thermoelectric module configured to (i) receive the return coolant from the processing chamber via the manifold assembly and prior to being returned to the cooling assembly, (ii) either one of heat and cool the return coolant, and (iii) supply heated return coolant and cooled return coolant to the coolant assembly.

2. The temperature control system of claim 1, wherein the thermoelectric module comprises:
a first conductive plate coupled to a first side of the thermoelectric module, the first conductive plate including first coolant channels in fluid communication with the manifold assembly and the coolant assembly to supply the return coolant from the manifold assembly to the coolant assembly; and
a second conductive plate coupled to a second side of the thermoelectric module, the second conductive plate including second coolant channels in fluid communication with the manifold assembly and the coolant assembly to supply the return coolant from the manifold assembly to the coolant assembly.

3. The temperature control system of claim 2, wherein the coolant assembly comprises a cold coolant reservoir and a hot coolant reservoir, and wherein:
the manifold assembly supplies the liquid coolant at the first temperature from the cold coolant reservoir and supplies the liquid coolant at the second temperature from the hot coolant reservoir.

4. The temperature control system of claim 3, wherein the first coolant channels supply the return coolant from the manifold assembly to the cold coolant reservoir and the second coolant channels supply the return coolant from the manifold assembly to the hot coolant reservoir.

5. The temperature control system of claim 4, wherein the manifold assembly comprises:
a first valve assembly configured to supply the liquid coolant from the cold coolant reservoir to the processing chamber;
a second valve assembly configured to supply the liquid coolant from the hot coolant reservoir to the processing chamber; and
a third valve assembly configured to supply the return coolant from the processing chamber to the thermoelectric module.

6. The temperature control system of claim 5, wherein the third valve assembly is configured to selectively supply the return coolant to either one of the first conductive plate and the second conductive plate.

7. The temperature control system of claim 6, wherein at least one of the first valve assembly, the second valve assembly and the third valve assembly comprises a 3-way valve.

8. The temperature control system of claim 1, further comprising a temperature controller configured to (i) control the manifold assembly to selectively control supply of the return coolant to the thermoelectric module and (ii) control a voltage supplied to the thermoelectric module to cool and heat the return coolant supplied to the coolant assembly.

9. The temperature control system of claim 1, wherein the thermoelectric module is located below the manifold assembly.

10. The temperature control system of claim 1, wherein the thermoelectric module is located laterally adjacent to the manifold assembly.

11. A substrate processing system comprising the temperature control system of claim 1 and further comprising the coolant assembly.

12. The substrate processing system of claim 11, wherein the coolant assembly is located below a floor of a fabrication room and the thermoelectric module is arranged above the floor.

13. The substrate processing system of claim 11, wherein the coolant assembly and the thermoelectric module are located below a floor of a fabrication room.

14. A temperature control system for a processing chamber, the temperature control system comprising:
a thermoelectric module arranged in a flow path between the processing chamber and a coolant assembly, the thermoelectric module configured to (i) receive return coolant from the processing chamber, (ii) either one of heat and cool the return coolant, and (iii) supply heated return coolant and cooled return coolant to the coolant assembly; and
a temperature controller configured to (i) selectively control supply of the return coolant to the thermoelectric module and (ii) control a voltage supplied to the thermoelectric module to cool and heat the return coolant supplied to the coolant assembly.

15. The temperature control system of claim 14, wherein the thermoelectric module comprises:
a first conductive plate coupled to a first side of the thermoelectric module, the first conductive plate including first coolant channels to supply the return coolant to the coolant assembly; and
a second conductive plate coupled to a second side of the thermoelectric module, the second conductive plate including second coolant channels to supply the return coolant to the coolant assembly.

16. The temperature control system of claim 15, wherein the thermoelectric module supplies the return coolant from the first conductive plate to a cold coolant reservoir of the coolant assembly and supplies the return coolant from the second conductive plate to a hot coolant reservoir of the coolant assembly.

17. The temperature control system of claim 15, further comprising a return valve assembly configured to supply the return coolant from the processing chamber to either one of the first conductive plate and the second conductive plate of the thermoelectric module.

18. The temperature control system of claim 17, wherein the return valve assembly comprises a 3-way valve.

19. The temperature control system of claim 17, wherein the temperature controller is configured to control the return valve assembly to selectively supply the return coolant to the first conductive plate or the second conductive plate of the thermoelectric module.

20. The temperature control system of claim 19, wherein the temperature controller is configured to control supply of voltage to the thermoelectric module to selectively cool and heat the return coolant within the first conductive plate and the second conductive plate, respectively.

21. The temperature control system of claim 1, further comprising the cooling assembly, wherein the cooling assembly is implemented as a dual channel chiller that is configured to heat and cool fluid received from the thermoelectric module.

22. The temperature control system of claim 1, wherein the thermoelectric module comprises:
a cold side plate receiving a first portion of the return coolant from the substrate support, comprising a cold side substrate, and directing the first portion of the return coolant to the cooling assembly;
a hot side plate receiving a second portion of the return coolant from the substrate support, comprising a hot side substrate, and directing the second portion of the return coolant to the cooling assembly; and
a plurality of thermoelectric semiconductor elements extending from the hot side substrate to the cold side substrate, wherein heat flows from the cold side substrate to the hot side substrate or vice versa based on a direction of current flow through the plurality of thermoelectric semiconductor elements.
